(19) United States
(12) Patent Application Publication
(10) Pub. No.: US 2022/0359423 A1
(43) Pub. Date: Nov. 10, 2022

(54) SEMICONDUCTOR DEVICE AND MANUFACTURING METHOD OF SEMICONDUCTOR DEVICE

(71) Applicant: Mitsubishi Electric Corporation, Tokyo (JP)

(72) Inventors: Yoshihiro YAMAGUCHI, Tokyo (JP); Daisuke OYA, Tokyo (JP)

(73) Assignee: Mitsubishi Electric Corporation, Tokyo (JP)

(21) Appl. No.: 17/623,201

(22) PCT Filed: Sep. 11, 2019
(86) PCT No.: PCT/JP2019/035628

§ 371 Date: Dec. 27, 2021

(51) Int. Cl. H01L 23/00; H01L 23/373; H01L 21/48

(52) U.S. Cl. CPC H01L 23/562; H01L 23/3735; H01L 21/4807

(57) ABSTRACT

The object is to provide a semiconductor device that enables reduction of deformation of a metal pattern due to a thermal stress and enhancement of reliability with respect to a heat cycle. A semiconductor device includes an insulation substrate, a metal pattern, a refinement region, and a semiconductor chip. The metal pattern is provided on an upper surface of the insulation substrate. The refinement region is provided in at least a partial region of a surface of the metal pattern. The refinement region contains a crystal grain smaller than a crystal grain of metal contained in the metal pattern outside the at least partial region of the surface. The semiconductor chip is mounted in the refinement region of the metal pattern.

### TECHNICAL FIELD

The present invention relates to a semiconductor device and a manufacturing method of a semiconductor device.

### BACKGROUND ART

In a semiconductor device, a semiconductor chip is mounted on a circuit pattern, i.e., a metal pattern, formed on an insulation layer, with a joining layer being interposed therebetween. Because linear expansion coefficients and sizes of each component, such as the semiconductor chip, the insulation layer, and the joining layer, are different, stresses are applied to each component depending on a temperature rise or a temperature drop of the semiconductor device. When there is a great strain, the joining layer is damaged, making the lifetime of the semiconductor device shorter. Thus, technology of improving performance of resistance to a heat cycle around the joining layer has been proposed. For example, a power semiconductor device described in Patent Document 1 includes a cured layer in a surface of a conductive layer on which a semiconductor element is mounted, so as to enhance reliability. A power module described in Patent Document 2 includes, as a circuit layer on a ceramic substrate to which a lead frame is joined, a circuit layer having Vickers hardness of 19 or higher, so as to improve joining reliability and heat dissipation performance.

### PRIOR ART DOCUMENTS

### Patent Documents

Patent Document 1: Japanese Patent Application Laid-Open No. 2014-187088
Patent Document 2: Japanese Patent Application Laid-Open No. 2017-152506

### SUMMARY

### Problem to be Solved by the Invention

As described above, owing to a temperature rise and drop caused by operation of the semiconductor chip, a thermal stress is applied due to a linear expansion coefficient difference between a metal pattern formed on an insulation substrate and the insulation substrate. For example, at the time of high temperature, a compression stress is generated in the metal pattern. A 45° direction with respect to a direction of the compression stress corresponds to a maximum shear stress, and thus a slip occurs in the metal pattern in a 45° direction with respect to a thickness direction of the metal pattern. When a crystal grain of metal forming the metal pattern is large, such a significant slip as to penetrate its crystal occurs. As a result, the surface of the metal pattern bulges, which deteriorates quality of the joining layer on the metal pattern as well. Repetition of such a thermal fatigue reduces the lifetime of the semiconductor device.

The present invention is made in order to solve the problems as described above, and has an object to provide a semiconductor device that enables reduction of deformation of a metal pattern due to a thermal stress and enhancement of reliability with respect to a heat cycle.

### Means to Solve the Problem

A semiconductor device according to the present invention includes an insulation substrate, a metal pattern, a refinement region, and a semiconductor chip. The metal pattern is provided on an upper surface of the insulation substrate. The refinement region is provided in at least a partial region of a surface of the metal pattern. The refinement region contains a crystal grain smaller than a crystal grain of metal contained in the metal pattern outside the at least partial region of the surface. The semiconductor chip is mounted in the refinement region of the metal pattern.

### Effects of the Invention

According to the present invention, the semiconductor device that reduces deformation of the metal pattern due to a thermal stress and enhances reliability with respect to a heat cycle can be provided.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view illustrating a configuration of a semiconductor device according to an embodiment.

FIG. 2 is a top view illustrating a configuration of the semiconductor device according to the embodiment.

FIG. 3 is a flowchart illustrating a manufacturing method of the semiconductor device according to the embodiment.

FIG. 4 is a flowchart illustrating details of a shot peening processing method according to the embodiment.

FIG. 5 is a top view illustrating a state in which a mask is placed on top of a ceramic substrate.

FIG. 6 is a diagram illustrating a relationship between Vickers hardness in a refinement region, a heat cycle, and a crack generated in the ceramic substrate.

### DESCRIPTION OF EMBODIMENTS

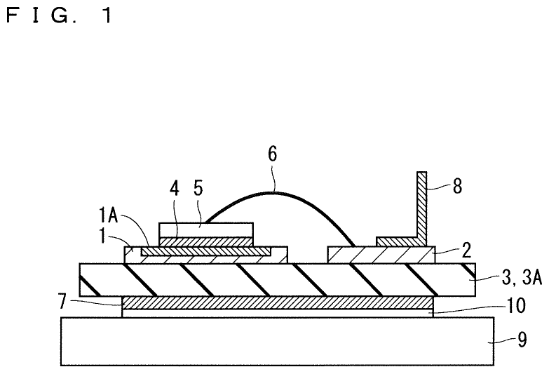

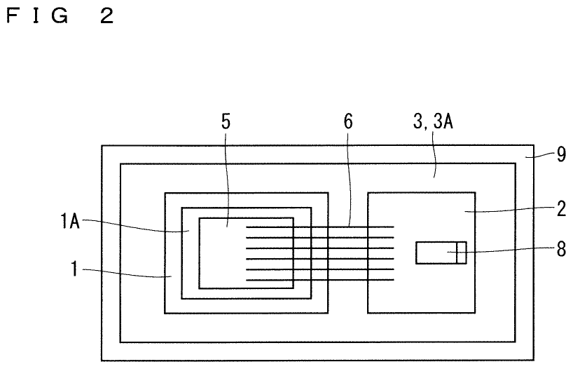

FIG. 1 and FIG. 2 are a cross-sectional view and a top view illustrating a configuration of a semiconductor device according to an embodiment, respectively.

The semiconductor device includes a base plate 9, a metal plate 7, an insulation substrate 3, a chip metal pattern 1, an external terminal metal pattern 2, a refinement region 1A, a semiconductor chip 5, and an external terminal 8.

Here, as an example, the insulation substrate 3 is a ceramic substrate 3A.

The chip metal pattern 1 and the external terminal metal pattern 2 are provided on the upper surface of the ceramic substrate 3A. The chip metal pattern 1 is a pattern for mounting the semiconductor chip 5. The external terminal metal pattern 2 is a pattern for mounting the external terminal 8. The material of the chip metal pattern 1 and the external terminal metal pattern 2 is, for example, aluminum or copper.

The refinement region 1A is a surface layer provided in a partial region of the surface of the chip metal pattern 1. In plan view, the refinement region 1A is disposed on the inner side with respect to the end portion of the chip metal pattern 1. The width from the end portion of the chip metal pattern 1 to the end portion of the refinement region 1A is equal to or larger than the thickness of the chip metal pattern 1.

A crystal grain of the metal contained in the chip metal pattern 1 in the refinement region 1A is smaller than a crystal grain of the metal contained in the chip metal pattern 1 outside the refinement region 1A. Further, Vickers hardness of the chip metal pattern 1 in the refinement region 1A is higher than Vickers hardness of the chip metal pattern 1 outside the refinement region 1A.

The semiconductor chip 5 is mounted above the refinement region 1A of the chip metal pattern 1, with the joining layer 4 being interposed therebetween. In other words, the refinement region 1A is formed immediately below the semiconductor chip 5. The material of the joining layer 4 is, for example, solder, sintered Ag, or sintered Cu. The semiconductor chip 5 is, for example, formed on a substrate whose material is a so-called wide-bandgap semiconductor such as SiC and GaN. The semiconductor chip 5 is, for example, an insulated gate bipolar transistor (IGBT), a metal oxide semiconductor field effect transistor (MOSFET), a Schottky barrier diode, or the like. The semiconductor chip 5 is, for example, a power semiconductor chip.

The external terminal 8 is joined on the external terminal metal pattern 2. The chip metal pattern 1 and the external terminal metal pattern 2 are connected to each other with a metal wire 6.

The metal plate 7 is joined to the lower surface of the ceramic substrate 3A. The metal plate 7 is joined to the surface of the base plate 9, using a joining member 10. Inside a container shape formed with a case (not illustrated) surrounding outer periphery of the ceramic substrate 3A and the base plate 9, the ceramic substrate 3A, on which the semiconductor chip 5 is mounted, is accommodated. The inside of the container shape is filled with a sealing material (not illustrated), in such a manner that the tip end of the external terminal 8 protrudes outside and the semiconductor chip 5 is sealed.

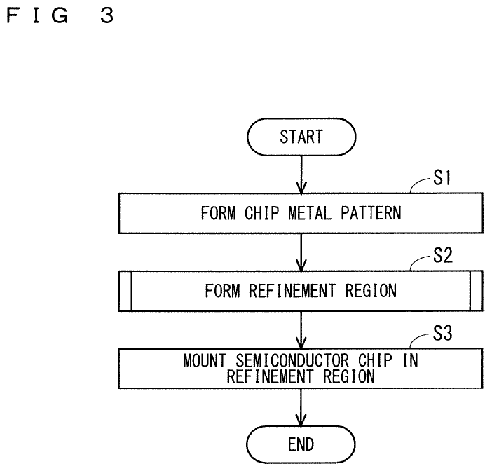

FIG. 3 is a flowchart illustrating a manufacturing method of the semiconductor device according to the embodiment.

In Step S1, the chip metal pattern 1 and the external terminal metal pattern 2 are formed on the upper surface of the ceramic substrate 3A.

In Step S2, the refinement region 1A is formed on a partial region of the surface of the chip metal pattern 1. Although the details will be described later, here, the refinement region 1A is formed through shot peening processing.

In Step S3, the semiconductor chip 5 is mounted in the refinement region 1A of the chip metal pattern 1, with the joining layer 4 being interposed therebetween. Subsequently, the external terminal 8 is mounted on the external terminal metal pattern 2, and the chip metal pattern 1 and the external terminal metal pattern 2 are connected to each other with the metal wire 6. Then, the metal plate 7 on the lower surface of the ceramic substrate 3A and the surface of the base plate 9 are joined together using the joining member 10. The inside of the container shape is filled with a sealing material, in such a manner that the semiconductor chip 5 and the ceramic substrate 3A are accommodated, the tip end of the external terminal 8 protrudes outside, and the semiconductor chip 5 is sealed inside the container shape formed with the case and the base plate 9.

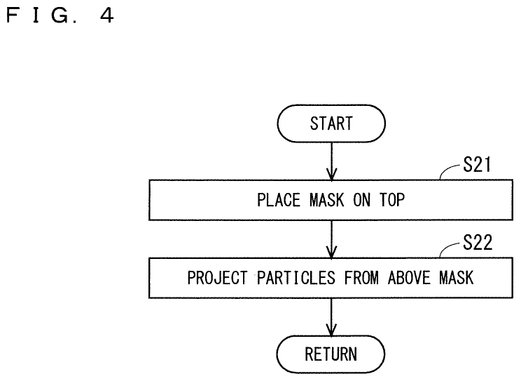

FIG. 4 is a flowchart illustrating details of a shot peening processing method in Step S2.

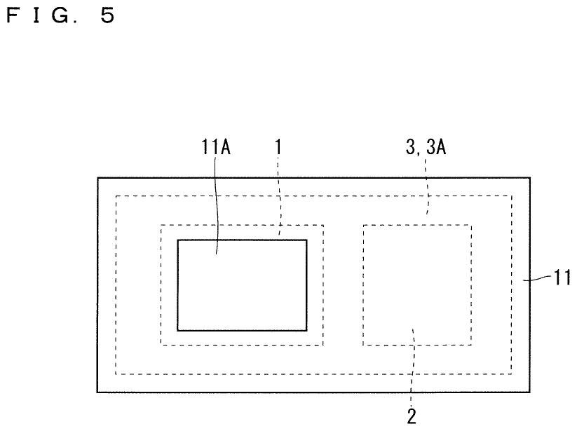

In Step S21, a mask having an opening is placed on top, in such a manner that the opening corresponds to the partial region of the chip metal pattern 1. FIG. 5 is a top view illustrating a state in which a mask 11 is placed on top of the ceramic substrate 3A. In this case, in plan view, an opening 11A of the mask 11 is disposed on the inner side with respect to the end portion of the chip metal pattern 1. The width from the end portion of the chip metal pattern 1 to the end portion of the opening 11A is equal to or larger than the thickness of the chip metal pattern 1. In other words, the opening 11A of the mask 11 overlaps the inner side with respect to outer periphery of the chip metal pattern 1. The mask 11 is, for example, made of metal.

In Step S22, particles are projected from above the mask 11. Through the shot peening processing of Steps S21 and S22 as above, in the surface of the chip metal pattern 1, fast large strain deformation occurs and a nanocrystal phase is formed. In other words, in the surface layer in the region subjected to the shot peening processing, the nanocrystal layer containing a crystal grain smaller than a crystal grain in the region not subjected to the shot peening processing is formed. Further, the surface layer is cured, and is harder than the chip metal pattern 1 outside the refinement region 1A. Further, in Step S22, the mask 11 inhibits collision of particles with the ceramic substrate 3A. With this, flexural strength of the ceramic substrate 3A is inhibited from being reduced.

Through the manufacturing method described above, the semiconductor device illustrated in FIG. 1 and FIG. 2 is manufactured.

The semiconductor chip 5 performs on/off control (switching control), based on a gate signal input from the external terminal 8, and the semiconductor device thereby controls power. In this case, depending on a value of loss generated in the semiconductor chip 5 and the like, temperature of the components constituting the semiconductor device rises or falls. At the time of high temperature in a heat cycle as above, a compression stress is generated in the chip metal pattern 1 due to a linear expansion coefficient difference between the chip metal pattern 1 and the ceramic substrate 3A. A 45° direction with respect to a direction of the compression stress corresponds to a maximum shear stress, and thus a slip occurs in a 45° direction with respect to a thickness direction of the chip metal pattern 1.

When the material used for the chip metal pattern 1 is high-purity aluminum, a crystal grain at the time of film formation is large, and for example, the aluminum layer is formed with approximately one crystal grain in the thickness direction. Further, aluminum easily plastically deforms, and thus such a significant slip as to penetrate one crystal grain occurs due to the shear stress in the 45° direction. The slip forms a bulge in the surface of the aluminum layer, and thus deteriorates quality of the joining layer 4 on the aluminum layer. In this manner, when the crystal grain of the chip metal pattern 1 immediately below the semiconductor chip 5 is large, the lifetime of the semiconductor device is reduced due to thermal fatigue such as the bulge in the chip metal pattern 1 and reduces quality deterioration of the joining layer 4.

In contrast, the chip metal pattern 1 according to the present embodiment includes the refinement region 1A, and the semiconductor chip 5 is mounted above the refinement region 1A, with the joining layer 4 being interposed therebetween. In the refinement region 1A of the chip metal pattern 1, fine crystal grains are stacked. Thus, even when a shear stress in the 45° direction is applied, such a significant slip as to penetrate one crystal grain is less liable to occur. Generation of a bulge in the surface of the chip metal pattern 1 is reduced, and quality of the joining layer 4 above the refinement region 1A is maintained. As a result, the lifetime of the semiconductor device is improved.

To summarize the above, the semiconductor device according to the present embodiment includes the ceramic substrate 3A, the chip metal pattern 1, the refinement region 1A, and the semiconductor chip 5. The chip metal pattern 1 is provided on the upper surface of the ceramic substrate 3A. The refinement region 1A is provided in at least a partial region of the surface of the chip metal pattern 1. Further, the refinement region 1A contains a crystal grain smaller than a crystal grain of metal contained in the chip metal pattern 1 outside the at least partial region of the surface. The semiconductor chip 5 is mounted in the refinement region 1A of the chip metal pattern 1.

The semiconductor device as described above reduces deformation of the chip metal pattern 1 due to a thermal stress and enhances reliability with respect to a heat cycle. In other words, the lifetime of the semiconductor device is improved. Note that the present embodiment illustrates an example in which the refinement region 1A is formed in a partial region of the surface of the chip metal pattern 1. However, the refinement region 1A may be formed in the entire region of the surface. In this case, the refinement region 1A contains a crystal grain smaller than a crystal grain of the chip metal pattern 1 that is located on the ceramic substrate 3A side rather than on its surface layer side.

Further, in plan view, the refinement region 1A according to the present embodiment is disposed on the inner side with respect to the end portion of the chip metal pattern 1. The width from the end portion of the chip metal pattern 1 to the end portion of the refinement region 1A is equal to or larger than the thickness of the chip metal pattern 1.

The refinement region 1A has high hardness, and thus when the refinement region 1A is formed up to the end portion of the chip metal pattern 1, a stress generated in the ceramic substrate 3A from the end portion is increased. The refinement region 1A according to the present embodiment has the configuration described above, and therefore the stress is relieved. As a result, reliability of the semiconductor device is enhanced.

Further, the manufacturing method of the semiconductor device according to the present embodiment includes the steps of: forming the chip metal pattern 1 on the upper surface of the ceramic substrate 3A; forming, in at least a partial region of the surface of the chip metal pattern 1, the refinement region 1A containing a crystal grain smaller than a crystal grain of metal contained in the chip metal pattern 1 outside the at least partial region of the surface; and mounting the semiconductor chip 5 in the refinement region 1A of the chip metal pattern 1.

The manufacturing method of the semiconductor device as described above enables manufacturing of the semiconductor device that reduces deformation of the chip metal pattern 1 due to a thermal stress and enhances reliability with respect to a heat cycle.

Further, forming the refinement region 1A according to the present embodiment includes shot peening processing of projecting particles to the at least partial region of the chip metal pattern 1.

The manufacturing method of the semiconductor device as described above enables formation of the refinement region 1A having enhanced hardness and having refined crystal grains at one time of processing.

Further, the shot peening processing according to the present embodiment includes placing the mask 11 having the opening 11A on top in such a manner that the opening 11A corresponds to the at least partial region of the chip metal pattern 1, and projecting the particles from above the mask 11. In plan view, the opening 11A of the mask 11 is disposed on the inner side with respect to the end portion of the chip metal pattern 1. The width from the end portion of the chip metal pattern 1 to the end portion of the opening 11A is equal to or larger than the thickness of the chip metal pattern 1.

With the shot peening processing, the manufacturing method of the semiconductor device as described above inhibits the ceramic substrate 3A from being subjected to damage, and inhibits the flexural strength thereof from being reduced. Further, reduction of a pattern size of the chip metal pattern 1, which is caused by, for example, removal of the end portion thereof due to collision of the particles or the like, is inhibited. In addition, as described above, formation of the refinement region 1A disposed on the inner side with respect to the end portion of the chip metal pattern 1 is enabled. As a result, reliability of the semiconductor device is enhanced. In other words, reduction of the lifetime of the semiconductor device due to a thermal fatigue is inhibited.

(First Modification of Embodiment)

The refinement region 1A according to the first modification of the embodiment is formed in processing of adding a dissimilar metal to at least a partial region of the chip metal pattern 1. For example, when the material of the chip metal pattern 1 is high-purity aluminum, one of A6063, A3003, and A5005, each being an alloy, is added to a partial region or the entire region of the surface at the time when or after the chip metal pattern 1 is formed. When addition concentration exceeds 20%, a stress on the ceramic substrate 3A is increased, and the lifetime of the semiconductor device is reduced due to the same reason as that described above, i.e., due to a thermal fatigue. Thus, it is preferable that the addition concentration be 20% or less. Through the processing, crystal grains of metal of the chip metal pattern 1 are refined.

(Second Modification of Embodiment)

In the second modification of the embodiment, Vickers hardness of the chip metal pattern 1 in the refinement region 1A is higher than Vickers hardness of the metal plate 7.

The semiconductor device as described above reduces stresses on the joining layer 4, and inhibits generation of a strain. Further, with the rest of the part having low strength, reliability of the semiconductor device is enhanced.

Further, it is preferable that Vickers hardness in the refinement region 1A be 22 or higher and 29 or lower. When Vickers hardness of the chip metal pattern 1 in the refinement region 1A is 22 or higher, a bulge in the surface of the chip metal pattern 1 due to a heat cycle and damage to the joining layer 4 due to the bulge are reduced.

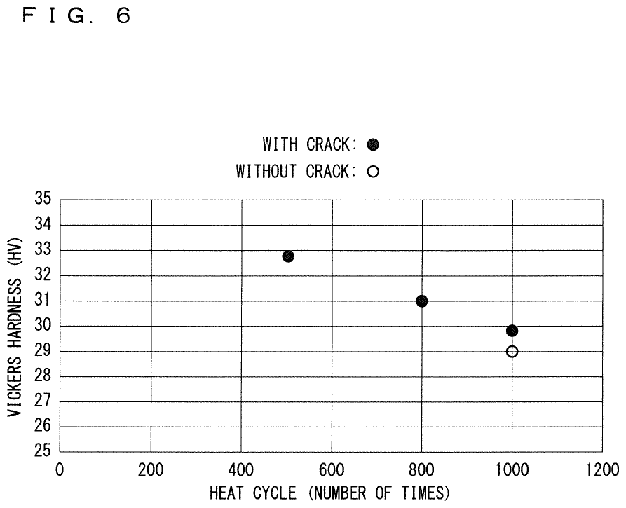

However, when Vickers hardness is excessively high, a stress on the ceramic substrate 3A due to a heat cycle is increased, and thus the lifetime of the semiconductor device is reduced. FIG. 6 is a diagram illustrating a relationship between Vickers hardness in the refinement region 1A, a heat cycle, and a crack generated in the ceramic substrate 3A. Here, one cycle corresponds to one cycle of a temperature change from −40° C. to 150° C. After the heat cycle is carried out 1000 times, a crack is generated in the ceramic substrate 3A when Vickers hardness is 30, whereas no cracks are generated when Vickers hardness is 29. This is because, when Vickers hardness in the refinement region 1A is 29 or lower, a stress on the ceramic substrate 3A is inhibited from increasing.

As described above, when Vickers hardness in the refinement region 1A is 22 or higher and 29 or lower, a bulge in the surface of the chip metal pattern 1 is reduced, and an excessive stress on the ceramic substrate 3A is reduced. By keeping a balance as described above, reliability of the semiconductor device is enhanced. The lifetime of the semiconductor device due to a thermal fatigue is improved.

Note that, in the present invention, the embodiment can be modified or omitted as appropriate within the scope of the invention.

While the invention has been shown and described in detail, the foregoing description is in all aspects illustrative and not restrictive. It is therefore understood that numerous unillustrated modifications can be devised without departing from the scope of the present invention.

### EXPLANATION OF REFERENCE SIGNS

1 Chip metal pattern, 1A Refinement region, 2 External terminal metal pattern, 3 Insulation substrate, 3A Ceramic substrate, 4 Joining layer, 5 Semiconductor chip, 6 Metal wire, 7 Metal plate, 8 External terminal, 9 Base plate, 10 Joining member, 11 Mask, 11A Opening

1. A semiconductor device comprising:
an insulation substrate;
a metal pattern provided on an upper surface of the insulation substrate;
a refinement region being provided in at least a partial region of a surface of the metal pattern, and containing a crystal grain smaller than a crystal grain of metal contained in the metal pattern outside the at least partial region of the surface; and
a semiconductor chip mounted in the refinement region of the metal pattern.

2. The semiconductor device according to claim 1, further comprising
a metal plate provided on a lower surface of the insulation substrate, wherein
Vickers hardness of the metal pattern in the refinement region is higher than Vickers hardness of the metal plate.

3. The semiconductor device according to claim 1, wherein
Vickers hardness of the metal pattern in the refinement region is 22 or higher and 29 or lower.

4. The semiconductor device according to claim 1, wherein
in plan view, the refinement region is disposed on an inner side with respect to an end portion of the metal pattern, and
width from the end portion of the metal pattern to an end portion of the refinement region is equal to or larger than thickness of the metal pattern.

5. A manufacturing method of a semiconductor device, comprising the steps of:
forming a metal pattern on an upper surface of an insulation substrate;
forming, in at least a partial region of a surface of the metal pattern, a refinement region containing a crystal grain smaller than a crystal grain of metal contained in the metal pattern outside the at least partial region of the surface; and
mounting a semiconductor chip in the refinement region of the metal pattern.

6. The manufacturing method of the semiconductor device according to claim 5, wherein
forming the refinement region includes shot peening processing of projecting particles to the at least partial region of the surface of the metal pattern.

7. The manufacturing method of the semiconductor device according to claim 6, wherein
the shot peening processing includes placing a mask having an opening on top in such a manner that the opening corresponds to the at least partial region of the metal pattern, and projecting the particles from above the mask,
in plan view, the opening of the mask is disposed on an inner side with respect to an end portion of the metal pattern, and
width from the end portion of the metal pattern to an end portion of the opening is equal to or larger than thickness of the metal pattern.

8. The manufacturing method of the semiconductor device according to claim 5, wherein
forming the refinement region includes processing of adding a dissimilar metal to the at least partial region of the surface of the metal pattern.

9. The semiconductor device according to claim 2, wherein
Vickers hardness of the metal pattern in the refinement region is 22 or higher and 29 or lower.

10. The semiconductor device according to claim 2, wherein
in plan view, the refinement region is disposed on an inner side with respect to an end portion of the metal pattern, and
width from the end portion of the metal pattern to an end portion of the refinement region is equal to or larger than thickness of the metal pattern.

11. The semiconductor device according to claim 3, wherein
in plan view, the refinement region is disposed on an inner side with respect to an end portion of the metal pattern, and
width from the end portion of the metal pattern to an end portion of the refinement region is equal to or larger than thickness of the metal pattern.

12. The semiconductor device according to claim 9, wherein
in plan view, the refinement region is disposed on an inner side with respect to an end portion of the metal pattern, and
width from the end portion of the metal pattern to an end portion of the refinement region is equal to or larger than thickness of the metal pattern.
